(19) United States
(12) Patent Application Publication
(10) Pub. No.: US 2006/0153262 A1
(43) Pub. Date: Jul. 13, 2006

(54) Terahertz quantum cascade laser

(75) Inventors: Stefano Barbieri, Cambridge (GB); Michael J Evans, Cambridge (GB)

Correspondence Address: DICKSTEIN SHAPIRO MORIN & OSHINSKY LLP, 2101 L Street, NW, Washington, DC, 20037, US

(73) Assignee: Teraview Limited, Cambridge (GB)

(21) Appl. No.: 10/530,733

(22) PCT Filed: Oct. 10, 2002
(86) PCT No.: PCT/GB02/04604

§ 371 Date: Feb. 21, 2006

(51) Int. Cl. H01S 5/00

(52) U.S. Cl. 372/43.01

(57) ABSTRACT

A laser comprising: a substrate comprising a bulk region and a conducting layer; an active region (11) comprising a quantum cascade structure provided on a first surface of the substrate (12) such that said active region (11) is electrically connected to said conducting layer; first and second contacts (16, 17) being disposed on opposite sides of said active region (11); and an active region contact (31) provided to said active region (11) such that a potential may be applied between said active region contact (31) and said first and second contacts (16, 17) to cause said active region (11) to lase.

The present invention relates to lasers and particularly to a quantum cascade lasers which exhibits continuous wave (CW) operation. More specifically, the present invention relates to the field of lasers which operate in the frequency range colloquially referred to as the TeraHertz frequency range, the range being that from 25 GHz to 100 THz, particularly that in the range of 50 GHz to 84 THz, more particularly that in the range from 90 GHz to 50 THz and especially that in the range from 100 GHz to 20 THz.

Conventional solid state lasers “pump” electrons into an excited state and emit light of a particular frequency when the excited electrons drop back to their ground state, thereby releasing the excess energy in the form of light. As all the electrons are “pumped” to the same degree they release the same amount of energy, which will be light of a particular frequency. The particular frequency of the emitted light can be determined from the equation E=hf, where f is the frequency of the emitted light, E is the energy of the photon, and h is Planck's constant.

Such solid state lasers have been used to generate electromagnetic radiation. It has, however, proven difficult to produce an efficient and powerful THz radiation source, as there is no good naturally occurring source of such radiation.

THz radiation, can be used for imaging samples and obtaining spectra at each pixel in an image. THz radiation penetrates most dry, non-metallic and non-polar objects like plastic, paper, textiles, cardboard, semiconductors and non-polar organic substances. Therefore THz radiation can be used instead of x-rays to look inside boxes, cases etc. THz radiation also has medical uses due to being non-ionizing.

Generally, continuous wave (CW) Terahertz radiation has been generated using p-doped Ge lasers and photomixers. However, p-doped Ge lasers have the disadvantage of requiring cooling at liquid Helium temperatures. Photomixers combine the difference frequency of two diode lasers. Although photomixers have the advantage of being able to operate at room temperature, the amount of power available using this technique is still confined to the μW level.

Recently, Köhler et al, Nature 417, 156 (2002) has reported Terahertz emission from a Quantum cascade laser (QCL).

Quantum cascade lasers were developed in 1994 by researchers at AT&T Bell Labs. QC lasers are a type of laser formed by a plurality of layers of different materials. In other words, the conduction band is made up of a number of sub-bands. In these lasers, electrons are again “pumped” but when they fall back to their ground state, the electrons effectively cascade down an energy staircase formed by the different sub-bands. At each step a photon of light is emitted. Therefore, instead of each electron emitting a single photon when falling to their normal state, as occurs with standard lasers, a number of photons are emitted. The amount of energy emitted and hence the wavelength for each photon can be controlled through the thickness of the layers. The radiation frequency is determined by the energy spacings of the sub-bands.

Although QCLs were developed which operated in the infra red frequency range, a terahertz QCL proved more difficult since it required thicker layers. Fabricating a device with thicker layers is not a problem per se, however, such devices did not lase since difficulties were encountered in recycling electrons within the device and guiding the photons out of the device. Köhler et al solved these problems.

The present invention seeks to improve the device of Köhler et al and provides a laser which may be configured to produce CW output in the Terahertz frequency range.

Thus, in a first aspect, the present invention provides a laser comprising:

a substrate comprising a bulk region and a conducting layer;

an active region comprising a quantum cascade structure provided on a first surface of the substrate such that said active region is electrically connected to said conducting layer;

first and second contacts provided to said conducting layer such that said first and second contacts are electrically connected to said active region, said first and second contacts being disposed on opposite sides of said active region; and

an active region contact provided to said active region such that a potential may be applied between said third contact and said first and second contacts to cause said active region to lase.

In the QCL of Köhler et al, a substrate with a conductive layer provided thereon is used to provide a part of the waveguide. A single contact is provided which is laterally disposed with respect to the active region. By using the contact arrangement of the present invention, the laser may be run in parallel, i.e. a bias may be applied between the first contact and the active region contact and the second contact and the active region contact. This allows a more uniform field to be applied across said active region which the inventors have found aids CW output.

More preferably, said first and second contacts are symmetric about said active region.

The above arrangement also, importantly, allows the series resistance to be minimised. The resistance measured between the first and active or second and active region contacts is the sum of the resistance through the active region and the series resistance. If the resistance of the laser is too high, then the operating temperature of the laser becomes too high to lase.

The inventors have found that the series resistance should preferably be comparable with or less than the resistance of the active region. The series resistance should be less than twice the resistance of the active region and preferably less than the resistance of the active region. As the total resistance is the sum of the series resistance and the resistance of the active region, the total resistance must be less than three times the resistance of the active region and preferably less than twice the resistance of the active region.

The series resistance may be reduced by either placing the first contact closer to the active region, increasing the resistivity of the conducting layer by increasing the doping of the layer, increasing its thickness etc.

The conducting layer may be a doped semiconductor. If the conducting layer is a semiconductor, it is preferably doped with a concentration of at least 1×10¹⁸ cm⁻³, more preferably at least 2×10¹⁸ cm⁻³.

To further reduce the series resistance, the conducting layer may be a metal layer. QCL lasers with a metal layer have been reported by Unterrainer et al Appl. Phys. Lett. 80 p3060 to 3062 (2002). However, these lasers did not operate at THz frequencies.

Thus, in a second aspect, the present invention provides a laser comprising:

a substrate comprising a bulk region and a metal conducting layer;

an active region comprising a quantum cascade structure provided on a first surface of the substrate such that the active region is electrically connected to said conducting layer, said active region being configured to emit radiation in the frequency range of up to 12 THz;

a first contact provided to said conducting layer such that said first contact is electrically connected to said active region; and

an active region contact provided to said active region such that a bias may be applied between said active region and said first contact to cause said active region to lase.

A second contact may be provided to said conducting layer on the opposing side of said active region to the first contact.

The conducting layer may preferably comprise any metal, for example: TiAu; GeAu; or GeAg

The laser of the second aspect of the present invention may be fabricated using a metal bonding technique. Thus, in a third aspect, the present invention provides a method of making a laser, the method comprising:

forming an active region which comprises a plurality of layers defining a quantum cascade laser structure overlying a first substrate, said active region being configured to emit radiation in the frequency range of up to 12 THz;

providing a first metal layer overlying said plurality of layers;

providing a second metal layer overlying a second substrate;

placing said first and second metal layers in contact under sufficient conditions such that said first and second metal layers bond to each other;

etching said structure to remove said first substrate and to expose a surface of said plurality of layers;

forming a first contact to the metal layer formed by the bonding of said first and second metal layers; and

forming an active region contact to said active region such that a bias may be applied between said first contact and said active region contact which causes said plurality of layers to lase.

Preferably, an indium layer is provided overlying either or both of said first and second metal layers to aid bonding of said first and second metal layers. This indium layer may consist of In or an In compound such as InAg, InPb, InAgPb or InSn etc.

Preferably, the laser operates in the frequency range from 20 GHz to 10 THz.

For lasers in accordance with either of the first and/or second aspects of the present invention, the first contact may be disposed on a surface of the conducting layer, but it may also contact the conducting layer through the substrate.

More preferably, said first and third contacts are symmetric about said active region.

As has been previously mentioned, the substrate which comprises both a conducting layer and a bulk region is used as a waveguide. In order to provide good waveguiding, the dielectric constant of the conducting layer is preferably negative relative to the dielectric constant of the surrounding layers.

Also, preferably, when the conducting layer comprises a semiconductor, the layer is thin enough, such that in operation, the two surface plasmons present at the two interfaces of the conducting layer merge into a single mode.

The active region itself is preferably formed in a strip provided on the substrate such that the laser has a strip waveguide structure.

Preferably the strips are cleaved to form facets at the short ends of the strip. One of these facets is preferably covered by a metal. More preferably, the metal is Au or NiCr.

The active region comprises a cascade laser structure comprising a lamination of layers having at least two different band gaps. The laser structure is configured such that two minibands are formed, where a transition between these two minibands causes photons to be emitted with the desired output frequency. Preferably the thickness and composition of the layers is configured such that Terahertz radiation is emitted by the laser.

The present invention will now be described with reference to the following non-limiting embodiments in which:

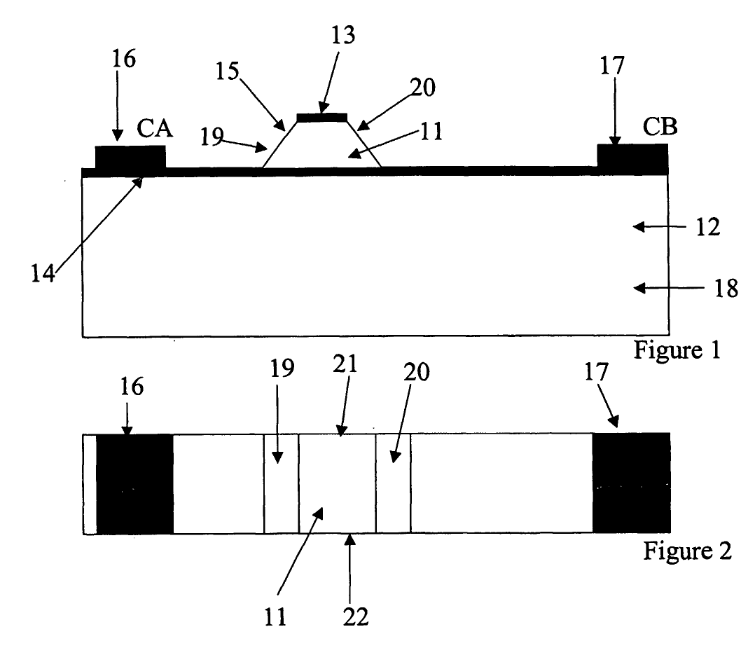

FIG. 1 is a simplified cross-section of a laser according to an embodiment of the present invention;

FIG. 2 illustrates a plan view of the laser in FIG. 1;

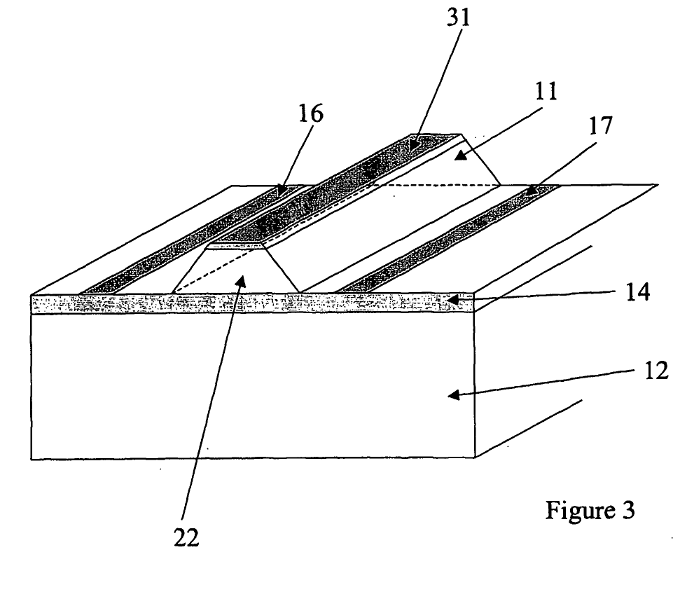

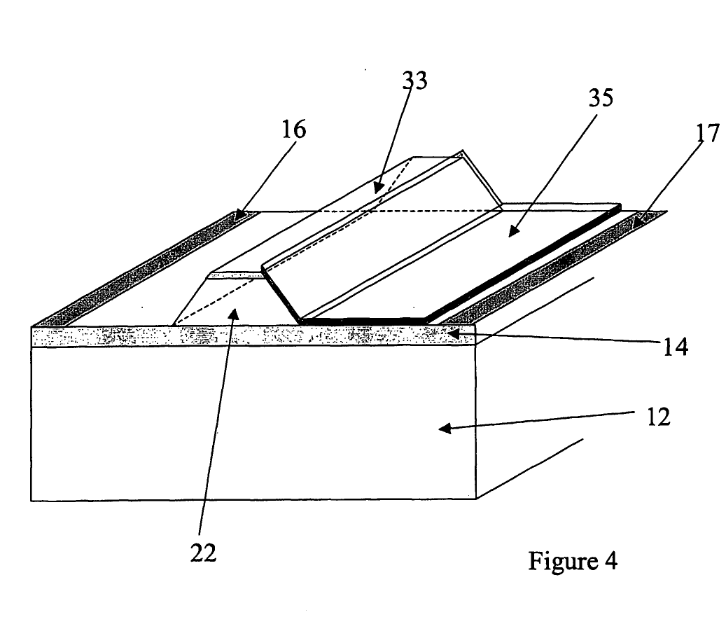

FIG. 3 illustrates a laser according to an embodiment of the present invention;

FIG. 4 illustrates a variation on the laser of FIG. 3;

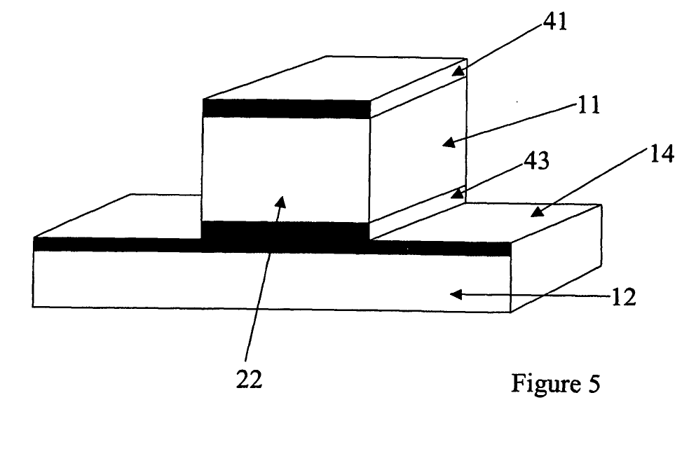

FIG. 5 illustrates a laser in accordance with a further embodiment of the present invention;

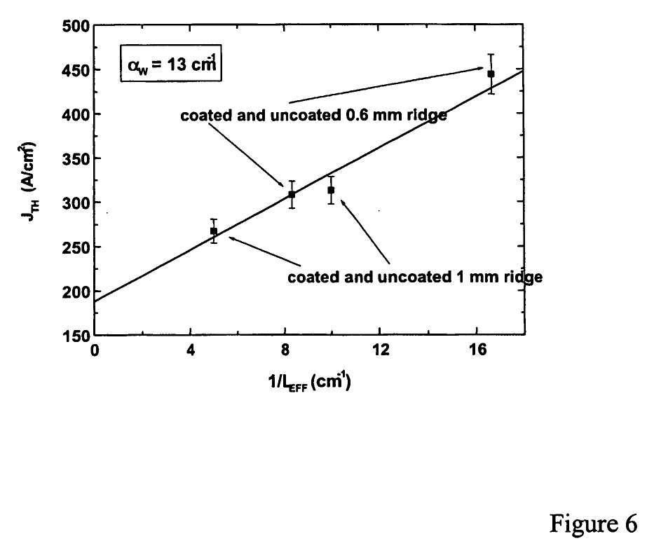

FIG. 6 illustrates a graph of threshold current density against effective inverse cavity length (1/L_{EFF}) for a 0.6 mm laser and a 1 mm laser according to FIG. 1 before and after back coating with a reflective material measured at 4K with 0.5% duty cycle;

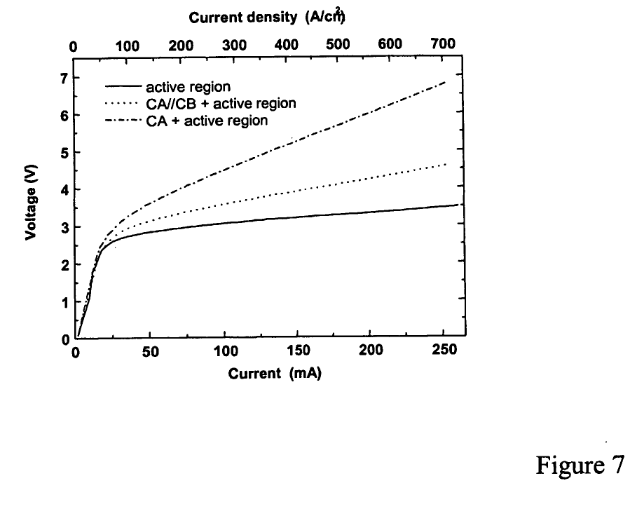

FIG. 7 graphically illustrates the current-voltage (I-V) characteristic of the laser of FIG. 1 for different contact configurations;

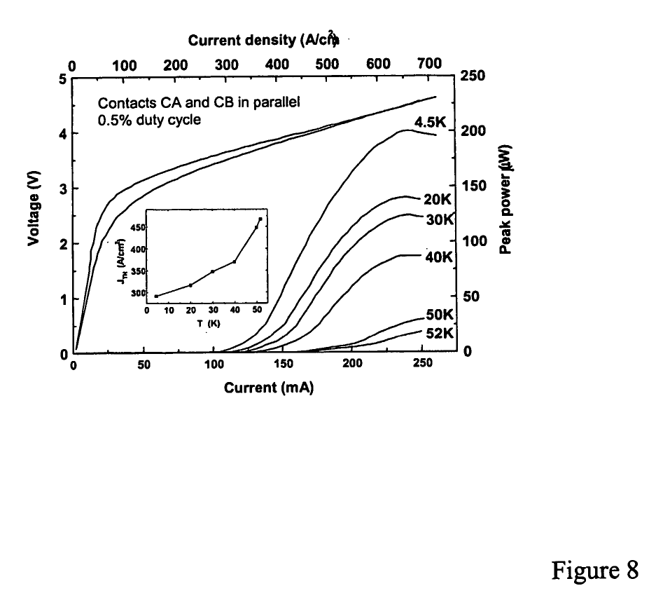

FIG. 8 illustrates pulsed light-current (L-I) characteristics of the laser of FIG. 1 measured at various heat sink temperatures. It also illustrates two I-V curves at 4K and 52K. The inset graph illustrates threshold current density as a function of the heat sink temperature;

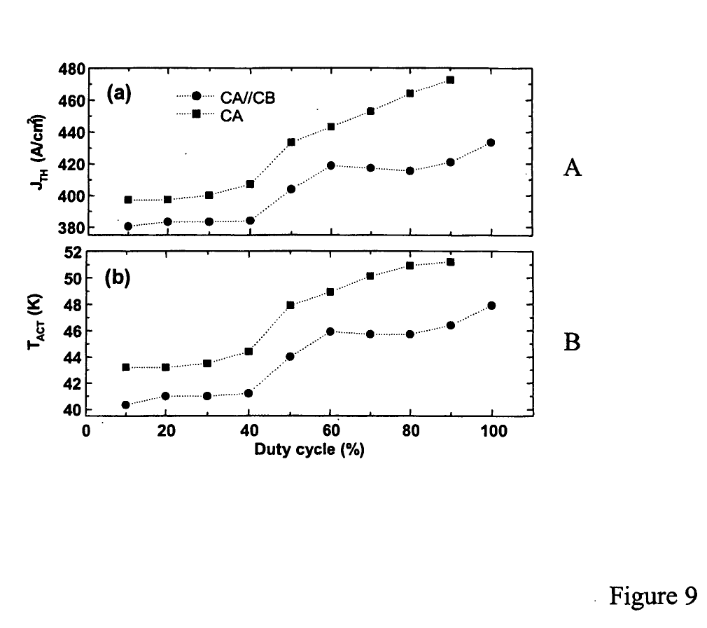

FIG. 9A illustrates a graph of threshold current density against duty cycle for contacts CA and CB in parallel (lower curve) and for contact CA only (upper curve);

FIG. 9B illustrates a graph of the temperature of the active region T_{ACT} against duty cycle for the contact configurations of CA and CB in parallel and CA only;

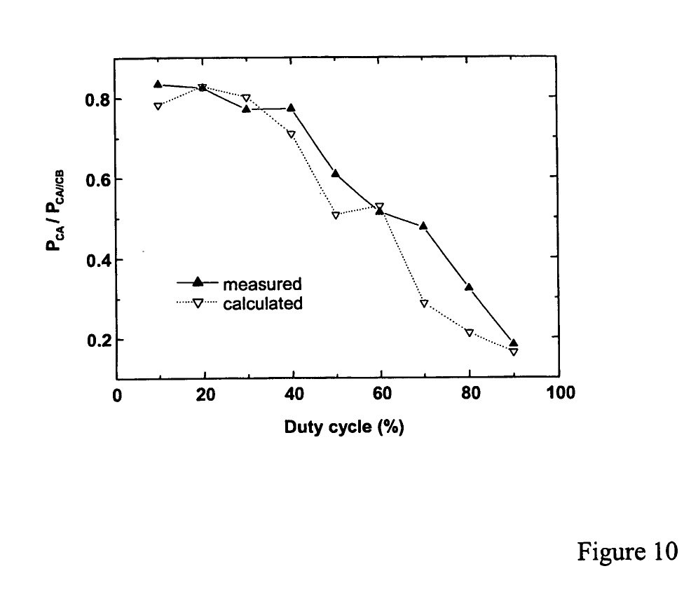

FIG. 10 illustrates a graph of the ratio of the collected powers in the two different contact configurations, (i.e. P_{CA}/P_{CA//CB}) as a function of the duty cycle;

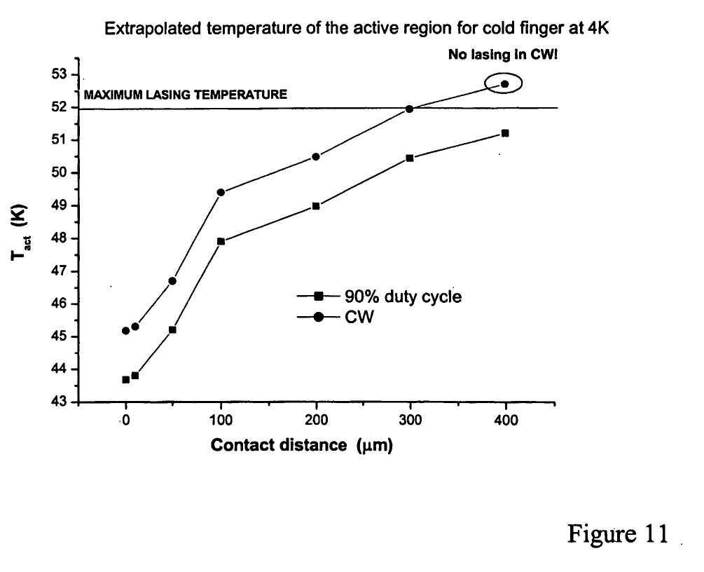

FIG. 11 illustrates a graph of temperature of the active region for different contact distances at 90% duty cycle and CW;

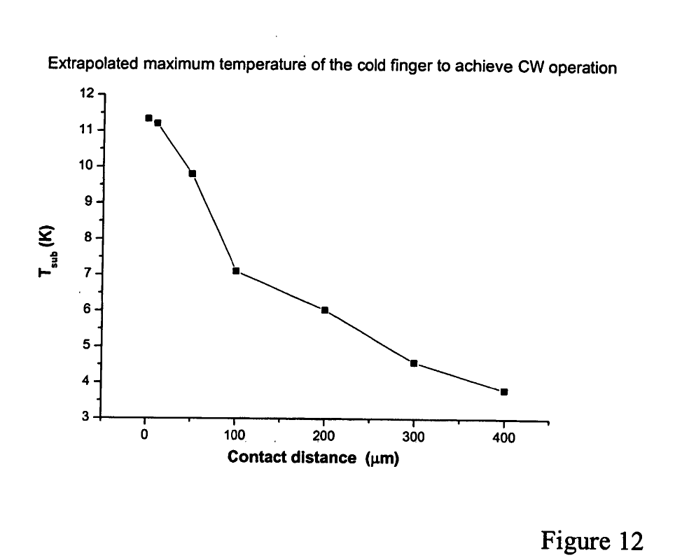

FIG. 12 illustrates a graph of maximum temperature of the cold finger of the cryostat to achieve CW operation for different contact distances;

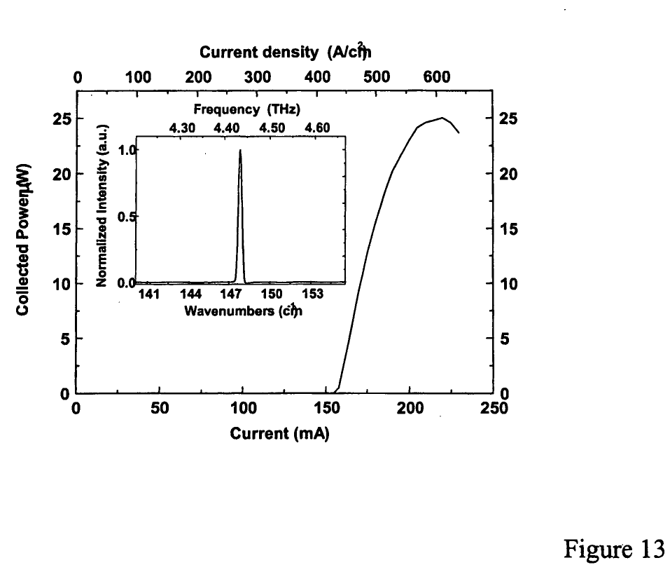

FIG. 13 illustrates the light-current (L-I) characteristics of a coated 0.6 mm laser of FIG. 1 operated in CW. The inset graph is a CW spectrum at 160 m.

An embodiment of the present invention will now be described with reference to FIGS. 1 and 2.

The QCL laser has an active region 1 provided on a surface of substrate 12. The substrate comprises a bulk insulating region 18 and conducting region 14 formed as a layer at the surface of said bulk region 18.

Said active region 11 forms a strip or ridge 15 on the surface of said conducting layer 14. The cross section of said strip is substantially trapezoidal, and arranged so that the largest parallel side of the trapezium is adjacent conducting layer 14. The two sloping sides 19, 20 of the trapezium lean inwards towards the top surface of the active region 11.

First (CA) and second (CB) lower contacts 16 and 17 respectively are provided to the conducting layer 14 on either side of said active region 11. A top contact 13 is provided to the top of said active region 11. The contacts are arranged such that application of a bias between the top contact 13 and one or both of the lower contact 16 and 17 causes a bias to be applied vertically across the active region 11. Upon application of a suitable bias, the active region will lase.

The active region 11 comprises a structure constructed by periodically stacking many repeated elementary layers. In this particular embodiment, the active region 11 is a hetero-structure consisting of 104 repeated 104.9 nm-long-periods of GaAs/Al_{0.15}Ga_{0.8}As. Each period comprises alternating layers of GaAs/Al_{0.15}Ga_{0.8}As, the layer thickness in nm of the layers of each period are 4.3 Al_{0.15}Ga_{0.8}As/18.8 GaAs/0.8 Al_{0.15}Ga_{0.8}As/15.8 GaAs/0.6 Al_{0.15}Ga_{0.8}As/11.7 GaAs/2.5 Al_{0.15}Ga_{0.8}As/10.3 GaAs/2.9 Al_{0.15}Ga_{0.8}As/10.2 GaAs/3.0 Al_{0.15}Ga_{0.8}As/10.8 GaAs/3.3 Al_{0.15}Ga_{0.8}As/9.9 GaAs. The first 7 layers constitute a superlattice comprising three closely coupled quantum wells, the remaining layers form an injector. The 10.2 GaAs layer being doped Si at a concentration of 4×10¹⁶ cm⁻³. Under appropriate bias, two mini-bands separated by an 18 MeV mini-gap are formed within each period of the superlattice. This arrangement can provide a frequency of 4.4 THz.

Alternative lasing structures may be used such as a GaAlInAs—InGaAs combination and a InAs/GaInSb/AlSb interband cascade laser. Also, in general, the thicker the layers within the active region, the longer the wavelength of radiation emitted by cascading electrons. Further, the larger the number of layers, the greater the number of photons emitted at once.

As described above, the substrate 12 comprises a bulk region 18 and a conducting layer 14. In this particular example, the conducting layer is 800 nm thick and doped with Si (n=2×10¹⁸). The total thickness of the bulk region 18 and conducting layer 14 is approximately 200 μm.

In order to act as an efficient waveguide for the emitted photons, the dielectric constant of the conducting layer ε_{A} is negative with respect to the dielectric constant of the surrounding semiconductor ε_{B}. During operation, two surface plasmons will exist at the two interfaces of the conducting layer 14. Layer 14 is made thin enough, so that these will merge into a single mode.

In addition to its waveguiding properties, the conducting layer 14 also provides a way to contact the active region 11 and thus contacts 16 and 17 are laterally disposed from the active region 11.

The laser structure of FIGS. 1 and 2 may be fabricated using a growth technique such as molecular beam epitaxy (MBE).

The active region 11 is formed into a ridge 15 by wet chemical etching the active region 11 down to the doped channel 14. After etching, the active region has a substantially trapezoid shape, so that a surface of the active region 11 above the surface level of the doped channel has a diameter which is less than the diameter of the active region 11 adjoining the doped channel 14.

In the present embodiment of the invention, the ridge is 60 μm wide at its widest along the edge adjoining the doped channel 14 as indicated by the distance x on FIG. 1, although this distance may readily vary, and a range of 20 to 500 microns could be expected.

FIG. 3 illustrates a laser in accordance with an embodiment of the present invention showing the contact arrangement in more detail. A top contact 31 is created over at least a portion of the active region. With reference to FIG. 3, the top contact 31 lies only on the upper surface of the active region 11. The top contact 31 is formed by depositing a metal strip on a GaAs layer on the upper surface of the active region 11. The metal strip, such as a Pd/Ge strip, may be defined using optical contact lithography. Preferably this strip is between 20 and 500 microns wide and with a length of more than 20 microns.

In the FIG. 3 example, the strip is 60 μm wide and 0.6 mm long. The contact is formed by annealing 25 nm of Pd and 75 nm of Ge at 350 degrees Celsius to form an ohmic contact. Although any suitable metallic materials may be used for the strip, a Pd/Ge alloy is useful as it has low diffusion into the semiconductor layers forming the active region 11. Typically the diffusion for Pd/Ge is limited to a few tens of nm.

Therefore, in effect, the active region 11 is embedded between a top contact 31 and the doped channel 14. In the present example the top contact 31 is a 200 nm thick GaAs layer and is doped at n=5×10¹⁸. This top contact 31, together with the doped channel 14, act as electrical contacts and also provide guiding layers from the emitted radiation.

Two lateral contacts CA, CB are created on the doped channel 14 on either side of the ridge 15 of the active region 11. These lateral contacts CA, CB may be formed by any means, such as by evaporation. Preferably these contacts are alloyed Ti/Au, but may also be provided by NiAuGe or other contacts which make a good ohmic contact with n-type material.

The lateral contacts CA, CB are spaced from the ridge 15 at a distance that minimises heating in the active region. How the optimal spacing is determined will be described shortly.

Once this structure has been created, lasers are cleaved out of the material. For example, in the present example the lasers cleaved out were 600 μm long Fabry-Perot cavities.

An alternative arrangement for the top contact is illustrated in FIG. 4. In this Figure, a doped GaAs layer 33 is provided on the top of the active region 11 as the top contact.

To allow external electrical connection to be made to this contact 33, a contact metal is used. First an insulator (not shown), such as polyamide, is deposited on the side of the ridge 11. Preferably this layer is 500 m thick. Contact metal 35 is then evaporated from the top of the ridge over the insulating layer. By forming the top contact in this way, it is possible to avoid bonding wires directly to the top of the ridge, which could damage the active region. The sloping sides of ridge 15 allow the contact metal to be evaporated without any discontinuities.

FIG. 5 illustrates a laser in accordance with a further embodiment of the present invention. To avoid unnecessary repetition, like reference numerals will be used to denote like features.

The embodiment of FIG. 5 differs from the previous embodiments primarily in that the conducting layer 14 is a metal layer as opposed to a highly doped semiconductor layer.

To form the structure of FIG. 5, the active region 11 and the substrate 12 are formed separately and are then connected using conducting metallic layer 14.

A 300 nm GaAs buffer layer is formed overlying and in contact with a first semi-insulating GaAs substrate. A 300 nm AlAs etch stop layer is then formed overlying and in contact with said GaAs buffer layer. An Si doped (5×10¹⁸ cm⁻³) first n⁺⁺ GaAs layer having a thickness of 500 nm is then formed overlying and in contact with said etch stop layer.

An active region comprising a superlattice of the type described with reference to FIG. 1, is formed overlying and in contact with said first n⁺⁺ GaAs layer. A second n⁺⁺ GaAs layer comprising 500 nm of Si doped (5×10¹⁸ cm⁻³) GaAs is then formed overlying and in contact with said active region 11.

Next a first TiAu layer 43 is evaporated over the second n⁺⁺ GaAs layer. A second TiAu layer 14 is evaporated over a second semi-insulating GaAs substrate 12. An indium layer is then evaporated over said second TiAu layer 14. The first 43 and second 14 metal layers are brought together to join the second substrate to the active region. The structure is then heated to melt the indium and bond the first metal layer to the second metal layer.

The first substrate is then etched down to the AlAs etch stop layer using a selective etch citric acid. The selective etch etches AlAs at 1/100 of the rate which it etches GaAs. AlAs is then etched using a further etcher and a TiAu layer 41 is deposited overlying second n⁺⁺ GaAs layer.

In the lasers of FIGS. 1 to 5, the laser has back 21 and front 22 facets. One or both of these facets may be coated in order to increase its reflectivity. Gold and nickel or a Ti/Au combination are materials suitable for such coatings, other materials may be used such as ZnSe or ZnAu. Where Ti/Au is utilised, appropriate thicknesses of the materials are 10 and 100 nm respectively.

By coating at least one of the facets 21,22 with a suitably reflective material the coating can act as a perfectly reflecting mirror, which allows the threshold current density to be reduced. This therefore assists in the ability of the laser to achieve CW operation. This is apparent by considering the expression relating to mirror loss:
α_{M}=½L×ln(R₁R₂) (1)
where L is the length of the ridge and R₁, R₂ are the reflectivities of the facets. For an uncoated facet, the reflectivity is approximately R_{U}=0.34, whereas for a coated facet, the reflectivity is approximately R_{C}=1. Therefore, at sub-mm wavelengths, an Au or Ni layer can act as a perfectly reflecting mirror.

Therefore, from this equation it is apparent that by coating one fact of the laser, a 50% reduction of the mirror losses can be obtained, from (1/L)ln(R_{U}) to (½L) ln(R_{U}). This is also equivalent to doubling the length of the cavity. So an effective cavity length L_{EFF} can be defined as L for an uncoated laser and 2 L for a coated one.

The reflective coating may then be preceded by the evaporated of a SiO₂ layer to prevent electrical shorting. Preferably this layer is 200 nm thick.

To illustrate the effectiveness of the coating, FIG. 6 graphically illustrates threshold current density against inverse cavity length (1/L_{EFF}) for a 0.6 mm laser and a 1 mm laser before and after back coating with a reflective material measured at 4K with 0.5% duty cycle. The four points correspond to threshold current densities measured before and after Ni/Au deposition over the back facet of the lasers. The points show that the back coating produces a 30% and 15% decrease of the threshold current density for the 0.6 mm laser and the 1 mm laser respectively. From the linearity of the measurements and from the threshold equation G×J_{TH}=α_{W}+αₘ a waveguide loss of approximately α_{w}=13 cm⁻¹ is obtained. In the above equation, G is the measured gain.

To operate the laser as described in any of FIGS. 1 to 5, it can be soldered to a copper holder with In or silver-epoxy and wire bonded. The copper holder is mounted on the cold finger of a He-flow cryostat, which acts as a heat sink.

To illustrate the operation of the laser of FIG. 1, FIG. 7 graphically represents the current-voltage (I-V) characteristic of the laser for different contact configurations at a temperature of 4K and operated in pulse mode with 200 ns pulse width and 25 kHz repetition rate. The upper curve represents current flowing into the active region through CA and a voltage drop measured between CA and the top contact 13 without CB being connected. The middle curve represents current flowing through CA and CB in parallel and voltage measured between the parallel of the two contacts and the top contact. The lower curve represents current flowing through CA and the voltage drop across CB and the top contact 13.

On the lowest IV curve, displaying the voltage drop across the bare active region, there is a dramatic increase of voltage from the point of zero current and zero voltage to about 2.5V at a current of 25 mA. The increase was essentially linear. From here, as the current is increased to 250 mA, there is little voltage increase, with the voltage only rising to approximately 3V. This therefore indicates a pronounced decrease of the differential resistance at approximately 3V, which is a clear signature for the onset of super-lattice mini-bands formation.

The increase in current is a consequence of super-lattice formation, as a highly conductive channel is opened across the whole active region from the 3V point, which equates to the “turn-on” bias.

By comparing the I-V characteristics of the various regions, it can be concluded that most of the current is flowing through contact CB, which is the contact closest to the top contact 13. This occurs even when contact CA and CB are connected in parallel.

By analysing the ohmic characteristics of the arrangement it can be shown that an advantage of operating the lateral contacts CA and CB in parallel is that the series resistance of the channel 14 can be reduced. This can be illustrated by subtracting the active region curve in FIG. 7 from the other two curves respectively. This shows that when the current is flowing through CA, the series resistance is 12.3 ohms and when flowing through CA and CB in parallel, 3.9 ohms. In order to operate the QC laser in continuous wave mode, the value of this resistance needs to be reduced as much as possible, so utilising the two contacts in parallel is advantageous.

While the laser could be operated only utilising lateral contact CB and not CA, a further advantage of driving both contacts in parallel is that it also gives a better electric field uniformity across the active region.

FIG. 8 illustrates pulsed light-current (L-I) characteristics for the laser of FIG. 1 measured at various temperatures of the heat sink, together with two I-V curves at 4K (upper curve) and 52K (lower curve). The laser was 600 microns long and 60 microns wide, was driven with CA and CB in parallel and had the back facet coated in gold. The pulse repetition rate was 25 kHz and the pulse length 200 ns. Power was collected with an f/1 parabolic mirror and directed into a liquid helium cooled calibrated Si-bolometer (QMC Ltd). The inset graph shows the threshold current density as a function of the temperature of the heat sink.

At 4.5K a threshold current of 108 mA was measured. By taking into account the area of the ridge, i.e. 60 μm×600 μm, this corresponds to a threshold current density of Jₜₕ=290 A/cm², as indicated on the inset graph at FIG. 6. Comparing the L-I characteristics, it is apparent that with increasing temperature, a decrease in the emitted power occurs, together with a rapid increase of the threshold current. This is more readily apparent by viewing the inset graph of threshold current density versus heat sink temperature. Therefore, for the laser of FIG. 1, 52K is approximately the maximum operating temperature in pulsed mode.

FIG. 9A graphically illustrates threshold current density against duty cycle for CA and CB in parallel (lower curve) and CA only (upper curve). The laser was driven in pulsed mode with a repetition rate of 330 Hz and a true duty cycle ranging from 10% up to 90%. FIG. 9A illustrates that a net threshold current reduction occurs when using the parallel contact configuration. In fact, with reference to FIG. 5, due to the lower operating voltage considerably less power is dissipated into the GaAs channel resulting in the active region having a lower temperature. This effect is more pronounced at higher duty cycles.

FIG. 9B graphically illustrates the temperature of the active region T_{ACT} against duty cycle for both contact configurations, CA and CB in parallel (lower curve) and CA only (upper curve). This graph was obtained by comparing the threshold current densities in FIG. 9A with the threshold current density versus temperature plot of FIG. 8. It was assumed that a 0.5% duty cycle heating was negligible, i.e. that the temperature of the active region and that of the heat sink were equal at this point).

In FIGS. 9A and 9B it is apparent that in the contact configuration for CA only, a 100% duty cycle cannot be achieved, as is indicated by the lack of measurement at 100% duty cycle for the CA measurements. In other words, CW operation is not possible for the laser of FIG. 1, where the contact configuration is CA only.

When only CA is used, at 90% duty cycle the temperature of the active region reaches 51K. Referring back to FIG. 8, it is to be recalled that 52K was found to be the maximum operating temperature for the laser of FIG. 1. Now referring to FIG. 9A, it is apparent from the graph relating to CA in parallel with CB, that an operating temperature increase of approximately 2K occurs from 90% duty cycle to CW operation at 100% duty cycle. As the relative increase is likely to be similar for the operation of CA only, it can therefore be readily deduced that when only CA is connected, T_{ACT}>53K at 100% duty cycle, which is greater than the maximum operating temperature for the laser of FIG. 1.

With reference to FIG. 9B, when the laser is driven in CW, that is, at 100% duty cycle, we obtain T_{ACT}=48K.

FIG. 10 graphically illustrates the ratio of the collected powers in the two different contact configurations, (i.e. P_{CA}/P_{CA//CB}) as a function of the duty cycle. The current is equal to 180 mA. The solid curve corresponds to measured values whereas the dotted one is obtained from the values of T_{ACT} of FIG. 9A. The agreement between the two curves is reasonable, providing further evidence that the temperature of the active region determines laser performance at high duty cycles.

Considering these measurements, an optimum contact distance can now be determined. Using the measured values in FIG. 9A of the threshold current at 90% duty cycle for CA at 400 microns and CB at 100 microns (which for present purposes is roughly equivalent to the measured values of the two contacts in parallel), the threshold current for different contact distances can be extrapolated to obtain the following relationship:
I_{TH}=144.67+0.06*d

Where I_{TH} is the current density in mA and d is the distance between the contact and the edge of the ridge on said substrate. This equation is simply obtained from a linear fit of the two measured thresholds.

In the same way, by measuring the differential resistance at 100 microns and 400 microns we can obtain a relationship showing the dependence of the differential resistance as a function of d:
R_{diff}=1.4667+0.02933*d

From the value of R_{diff} and the I-V characteristic of FIG. 7 measured across the active region only (which therefore excludes any resistance from the contacts) one can obtain the shape of the I-V characteristic for different d. From these curves one can obtain the voltage drop at threshold Vth.

Further, the temperature of the active region for a given d can be obtained from the following relationship:
T_{act}=T_{sub}+Rₜₕ*(Iₜₕ*Vₜₕ)

Where T_{act} is the temperature of the active region, T_{sub} is the temperature of the cold finger of the cryostat and Rₜₕ is the thermal resistance of the device as a whole. This latter parameter actually depends on d as well, since for a larger separation between the lateral contact and the ridge, heat is dissipated more easily, as the surface is bigger. From this equation, with CA at 100 microns and CB at 400 microns the value of R_{TH} can be obtained as well as the measured values of Iₜₕ and Vₜₕ at 0.5% duty cycle. At such a low duty cycle, in fact, we can assume that there is no heating effect, therefore T_{act}=T_{sub}=4.5K.

Therefore, at 400 microns Rₜₕ is 50 K/W and at 100 microns Rₜₕ is 72.3 K/W. By fitting these two points, the dependence of Rth on d can be estimated as:
Rₜₕ=79.73−0.0743*d(K/W)

Further, by combining the above equations relating to T_{act} and Rₜₕ, it is possible to obtain an equation defining the dependence of the temperature of the active region as a function of d.

FIG. 11 graphically illustrates temperature of the active region for different contact distances of the laser of FIG. 1 at 90% duty cycle and at 100% duty cycle. For CW operation at 100% cycle, the graph is an approximation from the 90% duty cycle values. From the CW graph, it is apparent that if d is greater than 300 microns, the temperature of the active region exceeds 52K, which is the maximum temperature deduced for lasing operation from the measurements at 0.5% duty cycle. Therefore, the laser of FIG. 1 does not work in CW for d greater than 300 microns when the cold finger of the cryostat is at 4.5K.

FIG. 12 illustrates the extrapolated maximum value of the temperature of the cold finger of the cyostat (T_{sub}) in order to lase in CW as a function of d.

To support the extrapolated data, reference is to be made to FIG. 13, which illustrates the light-current (L-I) characteristics of the coated 0.6 mm laser of FIG. 1 operated in CW. The laser was driven with both lateral contacts CA and CB connected in parallel, with a standard DC power supply. The distance of CA from the ridge was 100 microns and the distance of CB was 400 microns. Emitted power in the form of light was collected with an f/1 parabolic mirror and measured with a calibrated Golay cell detector (type OAD-7, QMC Ltd) and conventional lockin technique.

CW operation occurred at a heat sink temperature of 4K. When raising the temperature of the heat sink above 4K, laser action was suppressed within a few degrees K.

From the main graph of FIG. 13 it is apparent that a threshold current of 160 mA was obtained, which, taking the area of the ridge into consideration, corresponds to a current density of 440 A/cm². Also a maximum power of 25 μW was obtained.

The inset graph of FIG. 13 is a CW spectrum at 160 mA. The spectrum was collected with an FTIR (Fourier Transform Infrared) Spectrometer (Bruecker IV66S) in rapid scan and a room temperature DTGS (deuterated triglycine sulfate) detector. The emission wavelength is 67.6 μm, corresponding to energy of 18 meV.

By comparison with similar spectra obtained in pulsed operation no significant line narrowing could be observed, although the side-mode suppression decreased by a factor of 10 down to approximately 25 dB. This suggests that the line-width, being approximately 9.3 GHz was limited by the maximum resolution of the spectrometer, being 0.25 cm⁻¹.

Variations and additions are possible within the general inventive concept as will be apparent to those skilled in the art. It will be appreciated that the broad inventive concept of the present invention may be applied to any conventional type of QC laser and that the exact embodiment shown is intended to be merely illustrative and not limitative.

1. A laser comprising:
a substrate comprising a bulk region and a conducting layer;
an active region comprising a quantum cascade structure provided on a first surface of the substrate such that said active region is electrically connected to said conducting layer;
first and second contacts provided to said conducting layer such that said first and second contacts are electrically connected to said active region, said first and second contacts being disposed on opposite sides of said active region; and
an active region contact provided to said active region such that a potential may be applied between said active region contact and said first and second contacts to cause said active region to lase.

2. A laser according to claim 1, wherein the conducting layer comprises
a highly doped semiconductor.

3. A laser according to claim 2, wherein the conducting layer is thin enough, such that in operation, the two surface plasmons present at the two interfaces of the conducting layer merge into a single mode.

4. A laser according to 2, wherein the cascade laser is configured to emit photons having a frequency in the range from 0.02 THz to 100 THz.

5. A laser comprising:
a substrate comprising a bulk region and a metal conducting layer;
an active region comprising a quantum cascade structure provided on a first surface of the substrate such that the active region is electrically connected to said conducting layer, said active region being configured to emit radiation in the frequency range of up to 12 THz;
a first contact provided to said conducting layer such that said first contact is electrically connected to said active region; and
an active region contact provided to said active region such that a bias may be applied between said active region and said first contact to cause said active region to lase.

6. A laser according to claim 5, further comprising a second contact, provided to said conducting layer, on an opposing side of said active region to said first contact.

7. A laser according to claim 1, wherein the resistance between the first and active region contacts or second and active region contacts is less than three times the resistance of the active region.

8. A laser according to claim 1, wherein the resistance between the first and active region contacts or second and active region contacts is less than twice the resistance of the active region.

9. A laser according to claim 1, wherein said first and second contacts are symmetric about said active region.

10. A laser according to claim 1, wherein the dielectric constant of the conducting layer is negative relative to the dielectric constant of the surrounding layers.

11. A laser according to claim 1, wherein the active region comprises a strip waveguide.

12. A laser according to claim 1, wherein the active region comprises a lamination of layers having at least two different band gaps.

13. A method of fabricating a laser, the method comprising:
forming an active region which comprises a plurality of layers defining a quantum cascade laser structure overlying a first substrate;
providing a first metal layer overlying said plurality of layers;
providing a second metal layer overlying a second substrate;
placing said first and second metal layers in contact under sufficient conditions such that said first and second metal layers bond to each other;
etching said structure to remove said first substrate and to expose a surface of said plurality of layers;
forming a first contact to the metal layer formed by the bonding of said first and second metal layers; and
forming an active region contact to said active region such that a bias may be applied between said first contact and said active region contact which causes said plurality of layers to lase and output radiation in the frequency range up to 12 THz.

14. A method according to claim 13, wherein a layer comprising indium is provided overlying either or both of said first and second metal layers to aid bonding of said first and second metal layers.

15. (canceled)
